(19) United States
(12) Patent Application Publication
(10) Pub. No.: US 2008/0116578 A1
(43) Pub. Date: May 22, 2008

(54) Initiation layer for reducing stress transition due to curing

(76) Inventors: Kuan-Chen Wang, Hsinchu (TW); Zhen-Cheng Wu, Hsinchu (TW); Fang Wen Tsai, Hsinchu (TW); Yih-Hsing Lo, Hsinchu (TW); I-I Chen, Hsinchu City (TW); Tien-I Bao, Hsin-Chu (TW); Shwang-Ming Jeng, Hsin-Chu (TW)

Correspondence Address: SLATER & MATSIL, L.L.P., 17950 PRESTON ROAD, SUITE 1000, DALLAS, TX, 75252, US

(21) Appl. No.: 11/602,857

(22) Filed: Nov. 21, 2006

(51) Int. Cl. H01L 23/50; H01L 21/44

(52) U.S. Cl. 257/753; 438/598; 257/E23.079

(57) ABSTRACT

An integrated circuit includes an etch stop layer over a substrate; a UV blocker layer on the etch stop layer, wherein the UV blocker layer has a high extinction coefficient; and a low-k dielectric layer on the UV blocker layer.

### TECHNICAL FIELD

This invention is related generally to integrated circuits, and more particularly to fabrication processes of the interconnect structures in the integrated circuits.

### BACKGROUND

Conductive lines or interconnect structures are used to connect devices in integrated circuits and to connect to external pads. A significant problem in the formation of interconnect structures is the parasitic capacitances between metal lines. Parasitic capacitances cause an increase in RC delay. In some high-speed circuits, interconnect capacitances can be the limiting factor in the speed of the integrated circuit. It is thus desirable to reduce the interconnect capacitances. Accordingly, low dielectric constant (low k) materials have been increasingly used.

FIG. 1 illustrates an intermediate stage in the manufacture of an interconnect structure having a low-k dielectric layer. After the formation of a copper line 4 in a dielectric layer 2, an etch stop layer (ESL) 6 is formed, followed by the formation of a low-k dielectric layer 8. The primary purpose of ESL 6 is for stopping the etching process for low-k dielectric layer 8. In addition, ESL 6 provides a compressive stress to the overlying and/or underlying dielectric layers. Low-k dielectric layers typically have inherent tensile stresses. Stacked tensile layers tend to crack when the thicknesses are beyond a threshold called the cracking threshold. ESL 6 thus is typically formed with an inherent compressive stress, so that it provides a structure support to the semiconductor structure, preventing overlying and underlying low-k dielectric layers from cracking.

After the deposition of low-k dielectric layer 8, an ultraviolet (UV) curing is performed to drive porogen out of low-k dielectric layer 8 so that a porous structure is formed. The UV curing, however, also affects the ESL layer 6 due to the penetration of UV lights through low-k dielectric layer 8. Exposed to UV light, the stress in ESL 6 is typically changed toward the tensile side. For example, a sample ESL initially has a compressive stress of about 281 MPa. When exposed to UV light for about nine minutes, the stress is changed to a tensile stress of about 290 MPa. If exposed to UV light for nine more minutes, the tensile stress further increases to about 418 MPa.

One of the conventional methods to solve the problem is to form ESLs with a very high compressive stress when deposited. This high initial stress means that even though the stress of the ESLs are changed toward the tensile side after the UV curing, the resulting stress will still be compressive, although with a smaller value. Such a solution, however, suffers drawbacks. The highly compressive ESLs typically have high k values, resulting in degradation of the RC delay. High compressive stress may also cause wafer-cracking. In addition, with the complexity of forming highly compressive stressed ESLs, the throughput is also reduced.

### SUMMARY OF THE INVENTION

In accordance with one aspect of the present invention, an integrated circuit includes an etch stop layer over a substrate; a UV blocker layer on the etch stop layer, wherein the UV blocker layer has a high extinction coefficient; and a low-k dielectric layer on the UV blocker layer.

In accordance with another aspect of the present invention, a semiconductor structure includes a first dielectric layer over a semiconductor substrate; an etch stop layer comprising silicon carbonitride over the dielectric layer; an initiation layer on the etch stop layer, wherein the initiation layer has an extinction coefficient of greater than about 0.11 and a refractive index of greater than about 1.74 for a UV light used for curing; a low-k dielectric layer on the initiation layer, and a copper feature in the low-k dielectric layer.

In accordance with yet another aspect of the present invention, a method of forming an integrated circuit includes forming a dielectric layer over a semiconductor substrate; forming an etch stop layer over the dielectric layer; forming an initiation layer on the etch stop layer, wherein the initiation layer has an extinction coefficient of greater than about 0.11 for a UV light; forming a low-k dielectric layer on the initiation layer; and curing the low-k dielectric layer with the UV light.

In accordance with yet another aspect of the present invention, a method of forming an integrated circuit includes forming an etch stop layer having a compressive stress over a semiconductor substrate; forming a low-k dielectric layer over the etch stop layer; curing the low-k dielectric layer with an ultraviolet (UV) light; and attenuating the UV light from reaching the etch stop layer by forming a blocker layer between the low-k dielectric layer and the etch stop layer, wherein process conditions for forming the blocker layer are adjusted to increase an attenuation rate of the UV light penetrating the blocker layer.

With an UV blocker layer on the etch stop layer, the stress change in the etch stop layer due to UV curing is reduced.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates in intermediate stage in the manufacturing of an interconnect structure including a low-k dielectric layer; and

FIGS. 2 through 6 are cross-sectional views of intermediate stages in the manufacturing of a preferred embodiment.

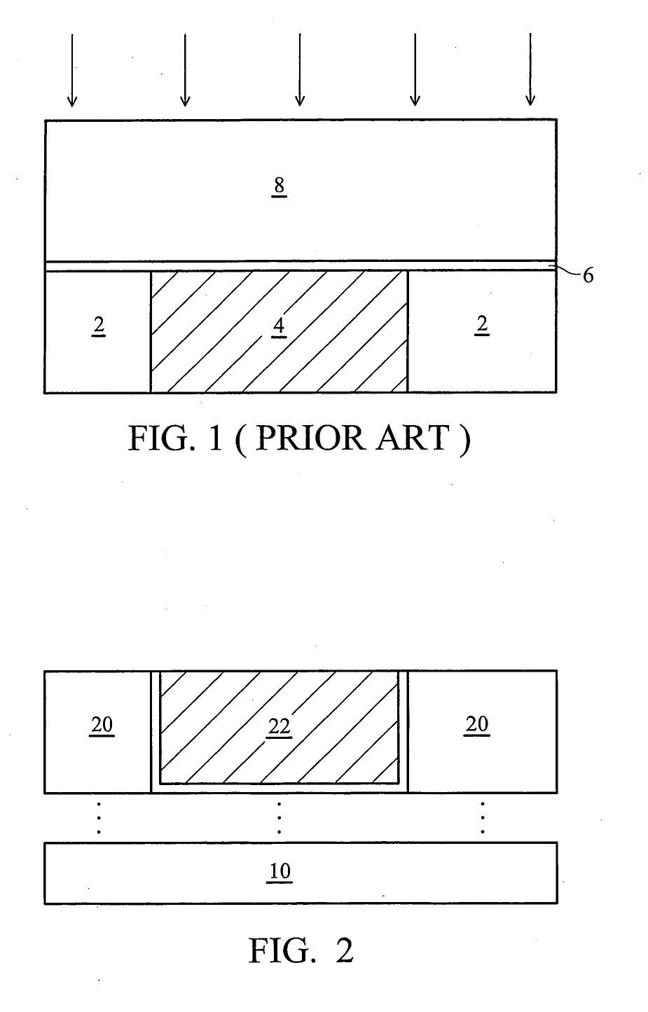

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A novel method for forming an interconnect structure is provided. The intermediate stages for manufacturing the preferred embodiment of the present invention are illustrated. Throughout the various views and illustrative embodiments of the present invention, like reference numbers are used to designate like elements. Although dual damascene processes are discussed in the preferred embodiment of the present invention, one skilled in the art will realize that the concept taught is readily available for the formation of single damascene processes.

FIG. 2 illustrates a starting structure having a metal line 22 formed in a dielectric layer 20. Metal line 22 and dielectric layer 20 are over a semiconductor substrate 10, which is preferably a silicon substrate having semiconductor devices formed thereon. Metal line 22 is preferably a metal line comprising copper, tungsten, aluminum, silver, gold, and combinations thereof. Metal line 22 is typically connected to another underlying feature (not shown), such as a via or a contact plug. Dielectric layer 20 may be an inter-layer dielectric (ILD) or an inter-metal dielectric (IMD), and preferably has a low k value. For simplicity, semiconductor substrate 10 is omitted from the remaining drawings.

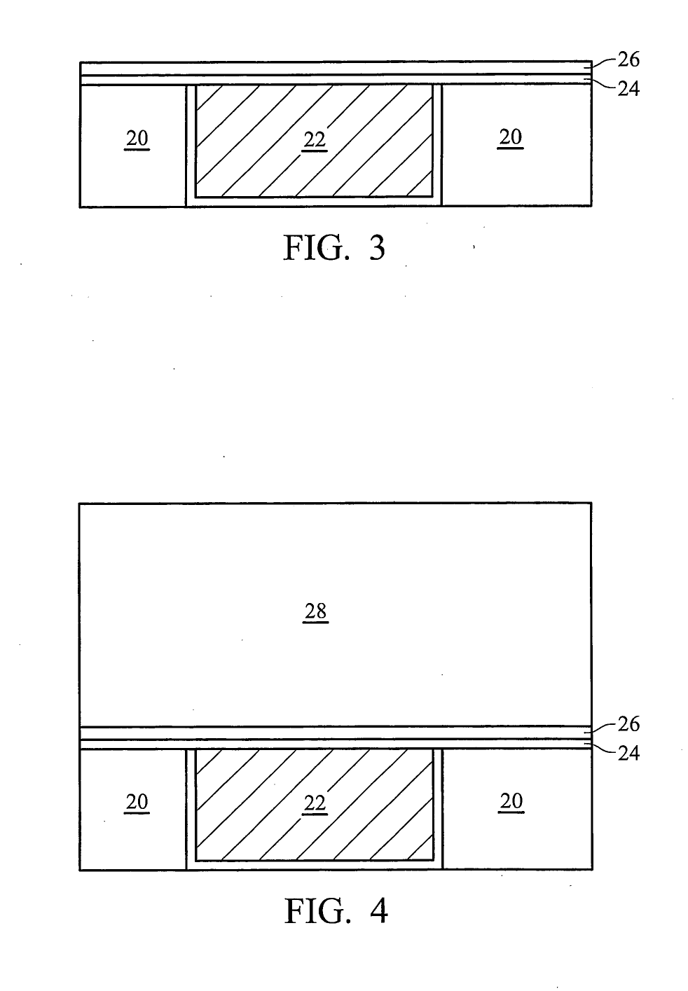

FIG. 3 illustrates the formation of an etch stop layer (ESL) 24 on dielectric layer 20 and metal line 22, followed by the formation of an initiation layer 26. In the preferred embodiment, ESL 24 comprises silicon carbonitride (SiCN). However, other commonly used materials such as silicon nitride (SiN), silicon oxycarbide (SiOC), silicon carbide (SiC), silicon oxynitride (SiON), and the like can also be used. ESL 24 preferably has a thickness of between about 150 Å and about 550 Å. The preferred formation methods include plasma enhanced chemical vapor deposition (PECVD) and other commonly used methods. In an exemplary embodiment, the precursors for forming ESL 24 include tetramethylsilane (4MS) and ammonia (NH₃), and the formation is performed at a wafer temperature of between about 345° C. and about 349° C., and more preferably about 350° C.

Initiation layer 26 is formed on ESL 24 and acts as an adhesion promoter. Initiation layer 26 has a better adhesion with the underlying ESL 24 and the subsequently formed overlying low-k dielectric layer than the adhesion between ESL 24 and the overlying low-k dielectric layer. Initiation layer 26 preferably includes silicon, oxygen, carbon, hydrogen, and combinations thereof.

Initiation layer 26 also acts as an ultraviolet (UV) blocker layer, and hence is referred to as a blocker layer throughout the description. When the low-k dielectric layer over the initiation layer 26 is formed and an UV curing is performed to cure the low-k dielectric layer, initiation layer 26 preferably blocks as much UV light as possible, so that the underlying ESL 24 is exposed to as little UV light as possible. In the preferred embodiment, initiation layer 26 has a relatively high extinction coefficient (k) and/or a high refractive index (n). As is known in the art, a high extinction coefficient and a high refractive index, particularly a high extinction coefficient, are beneficial for reducing the penetration of UV light. Preferably, the extinction coefficient of initiation layer 26 is about 0.11 or greater. The refractive index of initiation layer 26 is preferably about 1.74 or greater. Initiation layer 26 preferably has a thickness of between about 0.7 nm and about 45 nm, and is preferably formed using PECVD, high-density plasma chemical vapor deposition (HDPCVD), sub-atmospheric (SACVD), or the like.

It has been found that the extinction coefficient and the refractive index of initiation layer 26 are significantly affected by process conditions. In the experiments performed for studying the effects of the process conditions, a first sample initiation layer is formed with one set of process conditions, and the extinction coefficient and the refractive index are measured. The process conditions are then changed to form other sample initiation layers. The results have shown that by decreasing chamber pressure, decreasing mDEOS flow rate, decreasing RF power, and/or decreasing oxygen flow rate, the resulting sample initiation layers have increased extinction coefficients and increased refractive indices over the first sample initiation layer. This clearly indicates the effects of the process conditions on the extinction coefficient and the refractive index.

In the preferred embodiment of the present invention, the preferred process conditions for forming initiation layer 26 include a wafer temperature of between about 250° C. and about 350° C.; a chamber pressure of between about 1 torr and about 10 torr; a radio frequency (RF) power of between about 100 W and about 500 W; and a precursor flow rate of between about 100 sccm and about 500 sccm, wherein the precursors preferably include dimethyldiethoxysilane (mDEOS) and oxygen. The flow rate of oxygen is preferably less than about 450 sccm, and may even be turned off. In addition, the chamber may include a carrier gas such as helium, argon, nitrogen, and/or other inactive gases.

In an exemplary embodiment, a sample initiation layer 26 is in-situ formed with the overlying low-k dielectric layer, and is formed at a wafer temperature of about 260° C., a chamber pressure of about 4 torr, and a RF power of about 300 W. The precursor only includes mDEOS (with no oxygen added). Helium is used as the carrier gas, and mDEOS to helium have a flow rate ratio of about 0.04. The resulting sample initiation layer has a refractive index of about 1.74 and an extinction coefficient of about 0.11 for a UV light with a wavelength of about 248 nm. The same sample initiation layer has a refractive index of about 1.85 and an extinction coefficient of about 0.20 for a UV light with a wavelength of about 193 nm.

FIG. 4 illustrates the formation of a low-k dielectric layer 28, which provides the insulation between the metallization layers. Accordingly, low-k dielectric layer 28 is sometimes referred to as an inter-metal dielectric (IMD) layer. Low-k dielectric layer 28 preferably has a dielectric constant (k value) of lower than about 3.5, and more preferably lower than about 2.5 (hence is referred to as an extreme low-k dielectric layer, or ELK). The preferred materials include carbon-containing materials with porogens. Low-k dielectric layer 28 may be deposited using a chemical vapor deposition (CVD) method, preferably plasma enhanced CVD (PECVD), although other commonly used deposition methods such as low pressure CVD (LPCVD), atomic layer chemical vapor deposition (ALCVD), and spin-on can also be used. In the preferred embodiment, low-k dielectric layer 28 contains silicon, oxygen, carbon, hydrogen and combinations thereof. In an exemplary embodiment, the precursors include dimethyldiethoxysilane (also known as mDEOS), oxygen, and an organic compound 1-iso-propyl-4-methyl-1.3-cyclohexadiene (ATRP). More preferably, the formation of low-k dielectric layer 28 is performed in-situ with the formation of initiation layer 26.

It is known in the art that the extinction coefficient and refractive index are a function of the wavelength of the UV light, and with different UV lights having different wavelengths, the measured extinction coefficient and refractive index are different. Therefore, the preferred embodiment includes the steps of pre-determining the wavelength of the UV light and determining optimum process conditions for forming an ESL with a high extinction coefficient and refractive index.

An UV curing, which may be performed in a production tool that is also used for PECVD, atomic layer deposition (ALD), LPCVD, etc., is then performed. In an exemplary UV curing process, an ultraviolet radiator tool is used. The UV light preferably has a wavelength of between about 200 nm and about 300 nm, although UV lights with smaller or greater wavelengths may be used. As the extinction coefficient is a function of the wavelength of UV lights, after the formation of initiation layer 26, the extinction coefficient of initiation layer 26 to different UV lights is preferably measured, and a wavelength of the UV light is selected so that the corresponding extinction coefficient is high. The UV curing serves the functions of driving porogen out of low-k dielectric layer 28 and improving its mechanical property. Pores will then be generated in low-k dielectric layer 28 and its dielectric constant (k value) is reduced.

During the UV curing process, the UV light penetrates low-k dielectric layer 28. Initiation layer 26, with a high extinction coefficient and a high refractive index, attenuates a greater percentage of UV light from reaching the underlying ESL 24, thus acting as a UV blocker layer. As a result, the stress modulation (stress change to the tensile side) occurring in the ESL 24 is reduced.

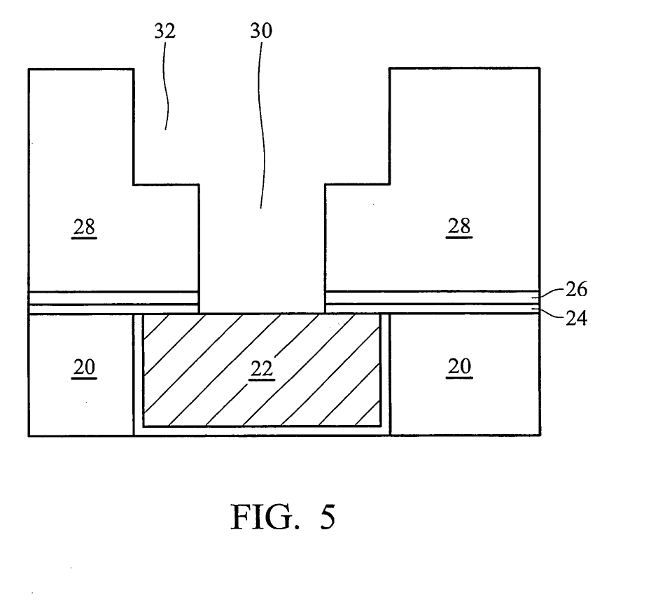

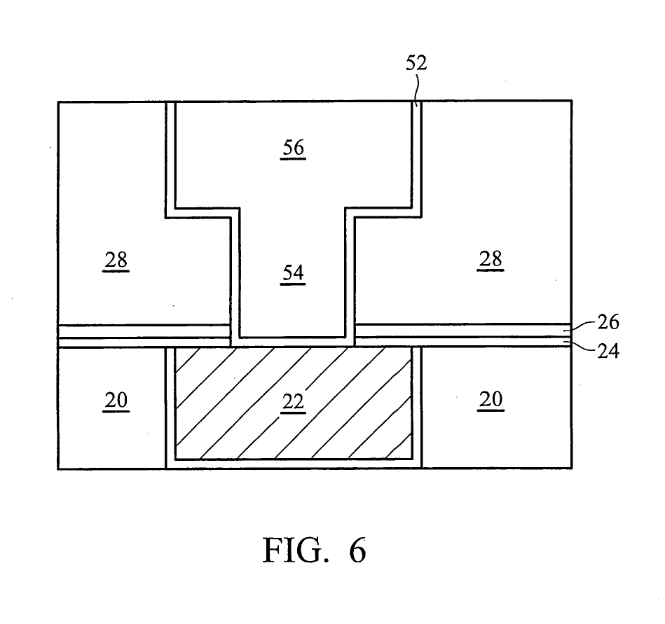

FIG. 5 illustrates the formation of a via opening 30 and a trench opening 32 in low-k dielectric layer 28. In the preferred embodiment, an anisotropic dry etching cuts through the low-k dielectric layer 28 and stops at ESL 24, thereby forming a via opening 30. Trench opening 32 is then formed. In alternative embodiments, a trench-first approach is taken, in which trench opening 32 is formed prior to the formation of via opening 30. Next, ESL 24 is etched through via opening 30, exposing underlying metal line 22.

FIG. 6 illustrates the formation of a diffusion barrier layer 52, a via 54 and a metal line 56. Diffusion barrier layer 52, which preferably includes titanium, titanium nitride, tantalum, tantalum nitride, and the like, is formed in the openings. Diffusion barrier layer 52 prevents the via materials, particularly copper, from diffusing into low-k dielectric layer 28 and causing circuit degradation. A seed layer (not shown) is formed on diffusion barrier layer 52, followed by the filling of a conductive material into via opening 30 and trench opening 32. The conductive material is preferably a metallic material including copper, tungsten, metal alloys, metal silicide, metal nitrides, and the like. Excess material is then removed using a chemical mechanical polish (CMP) process, leaving metal line 56 and via 54.

It should be appreciated that the concepts of the preferred embodiments of the present invention can also be applied to curing methods other than UV curing, such as eBeam curing, laser curing, and the like, if the curing adversely changes the stress of the ESL.

Experiments have been performed to verify the effects of the initiation layer 26. In a first sample device, a conventional initiation layer having an extinction coefficient of 2E-4 and a refractive index of 1.5 is formed on an ESL. In a second sample device, a preferred initiation layer having an extinction coefficient of 0.11 and a refractive index of 1.7 is formed on a similar ESL. In a third sample device, a similar ESL is formed, while there is no overlying initiation layer. The sample devices are then exposed under a UV light having a wavelength of about 248 nm. After a first UV exposure, it was found that in the first sample device, whose initiation layer has a relatively low extinction coefficient and a relatively low refractive index, the stress change is about 19 percent less than the stress change of the ESL layer in the third sample that does not have an initiation layer. In the second sample device, which has a relatively high extinction coefficient and a relatively high refractive index, the stress change is about 34 percent less than the stress change of the ESL layer in the third sample that does not have an initiation layer. This indicates that the initiation layer, particularly an initiation layer with a high extinction coefficient and refractive index, significantly reduces the stress change in the ESL due to UV exposure. If a second UV exposure is performed, the corresponding stress change improvements are about 11 percent for the first sample device and 28 percent for the second sample device.

By using the preferred embodiment of the present invention, the stress change caused by curing is reduced. The ESLs thus do not need to have very high compressive stresses at the time of deposition. As a result, ESL layers will have smaller dielectric constant values. The likelihood of wafer cracking is also reduced.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An integrated circuit comprising:
an etch stop layer over a substrate;
a UV blocker layer on the etch stop layer, wherein the UV blocker layer has a high extinction coefficient; and
a low-k dielectric layer on the UV blocker layer.

2. The integrated circuit of claim 1, wherein the extinction coefficient of the UV blocker layer is greater than about 0.11.

3. The integrated circuit of claim 1, wherein the UV blocker layer has a refractive index of greater than about 1.75.

4. The integrated circuit of claim 1, wherein the UV blocker layer comprises a material selected from the group consisting essentially of silicon, oxygen, carbon, hydrogen, and combinations thereof.

5. The integrated circuit of claim 1, wherein the UV blocker layer has a thickness of between about 70 nm and about 450 nm.

6. The integrated circuit of claim 1, wherein the etch stop layer has a compressive stress.

7. The integrated circuit of claim 1, wherein the low-k dielectric layer has a k value of less than about 2.5.

8. The integrated circuit of claim 1 further comprising a copper line and a via in the low-k dielectric layer.

9. The integrated circuit of claim 1, wherein the etch stop layer comprises a material selected from the group consisting essentially of silicon carbonitride, silicon oxynitride, silicon carbide, silicon nitride, silicon oxycarbide, and combinations thereof.

10. A semiconductor structure comprising:
a dielectric layer over a semiconductor substrate;
an etch stop layer comprising silicon carbonitride over the dielectric layer;
an initiation layer on the etch stop layer, wherein the initiation layer has an extinction coefficient of greater than about 0.11 and a refractive index of greater than about 1.75 for a UV light used for curing;
a low-k dielectric layer on the initiation layer; and
a copper feature in the low-k dielectric layer.

11. The semiconductor structure of claim 10, wherein the initiation layer is an adhesion promoter for the low-k dielectric layer and the etch stop layer.

12. The semiconductor structure of claim 10, wherein the initiation layer has a thickness of between about 70 nm and about 450 nm.

13. A method of forming an integrated circuit, the method comprising:
forming a dielectric layer over a semiconductor substrate;
forming an etch stop layer over the dielectric layer;
forming an initiation layer on the etch stop layer, wherein the initiation layer has an extinction coefficient of greater than about 0.11 for a UV light;
forming a low-k dielectric layer on the initiation layer; and
curing the low-k dielectric layer with the UV light.

14. The method of claim 13, wherein the step of forming the initiation layer comprises plasma enhanced chemical vapor deposition (PECVD).

15. The method of claim 13, wherein the step of forming the initiation layer is performed with a wafer temperature of between about 250° C. and about 350° C.

16. The method of claim 13, wherein the step of forming the initiation layer is performed with a chamber pressure of between about 1 torr and about 10 torr.

17. The method of claim 13, wherein the step of forming the initiation layer is performed with a RF power of between about 100 W and about 500 W.

18. The method of claim 13, wherein the step of forming the initiation layer is performed with a precursor flow rate of between about 100 sccm and about 500 sccm, and wherein the precursor comprises dimethyldiethoxysilane (mDEOS) and oxygen.

19. The method of claim 18, wherein oxygen has a flow rate of less than about 450 sccm.

20. The method of claim 19, wherein the precursor is substantially free from oxygen.

21. The method of claim 13, wherein the step of forming the initiation layer is performed in-situ with the step of forming the low-k dielectric layer.

22. The method of claim 13, wherein the step of curing is performed with a UV light having a wavelength of between about 200 nm and about 300 nm.

23. The method of claim 13, wherein the step of forming the initiation layer comprises:
determining a wavelength of the UV light; and
adjusting process conditions for the step of forming the initiation layer based on the wavelength of the UV light to increase the extinction coefficient of the initiation layer.

24. A method of forming an integrated circuit, the method comprising:
forming an etch stop layer having a compressive stress over a semiconductor substrate;
forming a low-k dielectric layer over the etch stop layer;
curing the low-k dielectric layer with an ultraviolet (UV) light; and
attenuating the UV light from reaching the etch stop layer by forming a blocker layer between the low-k dielectric layer and the etch stop layer, wherein process conditions for forming the blocker layer are adjusted to increase an attenuation rate of the UV light penetrating the blocker layer.

25. The method of claim 24, wherein the blocker layer has an extinction coefficient of greater than about 0.11.

26. The method of claim 25, wherein the blocker layer has an adhesion with the etch stop layer and the low-k dielectric layer better than the adhesion between the low-k dielectric layer and the etch stop layer.
